(19) United States
(12) Patent Application Publication
(10) Pub. No.: US 2025/0353404 A1
(43) Pub. Date: Nov. 20, 2025

(54) BATTERY SYSTEM, VEHICLE, METHOD OF CONTROLLING BATTERY SYSTEM, AND NON-TRANSITORY STORAGE MEDIUM

(71) Applicant: TOYOTA JIDOSHA KABUSHIKI KAISHA, Toyota-shi (JP)

(72) Inventors: Yukinori MURAKAMI, Toyota-shi (JP); Yuma MIYAMOTO, Miyoshi-shi (JP); Yohei HOSOKAWA, Susono-shi (JP); Kazuki MATSUMURA, Toyota-shi (JP); Yoshiyuki TAKAHARA, Toyota-shi (JP); Koji ITO, Nagoya-shi (JP)

(73) Assignee: TOYOTA JIDOSHA KABUSHIKI KAISHA, Toyota-shi (JP)

(21) Appl. No.: 19/171,738

(22) Filed: Apr. 7, 2025

(30) Foreign Application Priority Data
May 15, 2024 (JP) 2024-079581

(51) Int. Cl. B60L 58/20; B60L 50/60; B60L 53/51; B60L 53/62; H01M 10/42; H01M 10/46; H02J 7/00; H02J 7/34; H02J 7/35

(52) U.S. Cl. CPC B60L 58/20; B60L 50/60; B60L 53/51; B60L 53/62; H01M 10/425; H01M 10/46; H02J 7/00712; H02J 7/342; H02J 7/35; B60L 2210/14; H01M 2220/20

(57) ABSTRACT

A battery system includes a low-voltage battery, a high-voltage battery having a higher rated voltage than the low-voltage battery, and a processing circuit configured to control charging of the high-voltage battery from the low-voltage battery. The processing circuit is configured to execute determining whether a stored electricity amount of the low-voltage battery is greater than a determination stored electricity amount, and controlling charging of the high-voltage battery such that the high-voltage battery is charged with a predetermined amount of electricity from the low-voltage battery on condition that the processing circuit determines that the stored electricity amount of the low-voltage battery is greater than the determination stored electricity amount.

### CROSS-REFERENCE TO RELATED APPLICATION

This application claims priority to Japanese Patent Application No. 2024-079581 filed on May 15, 2024, incorporated herein by reference in its entirety.

### BACKGROUND

### 1. Technical Field

The present disclosure relates to a battery system, a vehicle, a method of controlling a battery system, and a non-transitory storage medium.

### 2. Description of Related Art

U.S. Pat. No. 10,052,967 discloses an example of a battery system including a low-voltage battery, and a high-voltage battery having a higher rated voltage than the low-voltage battery. In the battery system, charging of the high-voltage battery from the low-voltage battery is performed until the charging rate of the high-voltage battery reaches a predetermined charging rate.

### SUMMARY

The charging rate characteristic of the high-voltage battery may change due to, for example, the progression of deterioration of the high-voltage battery. The charging rate characteristic is a characteristic that shows the relationship between the amount of electricity stored in the high-voltage battery and the charging rate. When the charging rate characteristic of the high-voltage battery changes, even if the high-voltage battery is charged until the charging rate reaches a predetermined charging rate, the amount of electricity stored in the high-voltage battery may not reach a desired amount.

A battery system according to the present disclosure includes a low-voltage battery, a high-voltage battery having a higher rated voltage than the low-voltage battery, and a processing circuit configured to control charging of the high-voltage battery from the low-voltage battery. The processing circuit is configured to execute determining whether a stored electricity amount of the low-voltage battery is greater than a determination stored electricity amount, and controlling charging of the high-voltage battery such that the high-voltage battery is charged with a predetermined amount of electricity from the low-voltage battery on condition that the processing circuit determines that the stored electricity amount of the low-voltage battery is greater than the determination stored electricity amount.

The low-voltage battery may be configured to be charged with electric power supplied from a solar power generation system.

The battery system may be mounted on a vehicle, and the low-voltage battery and the high-voltage battery may be configured to supply electric power to a component mounted on the vehicle.

The battery system may further include a bidirectional DC-DC converter. The processing circuit may be configured to boost a voltage of direct current electric power output from the low-voltage battery to charge the high-voltage battery from the low-voltage battery.

The processing circuit may be configured to set the predetermined amount of electricity in accordance with a state of the high-voltage battery.

The processing circuit may be configured to set the predetermined amount of electricity based on at least one of a charged state and a deteriorated state of the high-voltage battery.

The processing circuit may be configured to set the predetermined amount of electricity such that the predetermined amount of electricity is greater when a frequency of charging the high-voltage battery from the low-voltage battery is high than when the frequency is low.

The processing circuit may be configured to execute determining whether a capacity of the low-voltage battery is equal to or less than a determination capacity, and making the predetermined amount of electricity smaller when the processing circuit determines that the capacity of the low-voltage battery is equal to or less than the determination capacity than when the processing circuit determines that the capacity is greater than the determination capacity.

The processing circuit may be configured to set the predetermined amount of electricity such that a voltage of the low-voltage battery does not fall below a lower limit guard.

The processing circuit may be configured to set the lower limit guard on condition that the processing circuit determines that a capacity of the low-voltage battery is equal to or less than a threshold.

On condition that a voltage of the high-voltage battery becomes higher than a specified voltage while charging of the high-voltage battery from the low-voltage battery is being performed, the processing circuit may be configured to stop the charging of the high-voltage battery.

A vehicle of the present disclosure includes the battery system described above, and a traction motor configured to be driven by electric power supplied from the high-voltage battery.

A method of controlling a battery system according to the present disclosure is a method of controlling a battery system including a low-voltage battery, and a high-voltage battery having a higher rated voltage than the low-voltage battery. The controlling method includes determining whether a stored electricity amount of the low-voltage battery is greater than a determination stored electricity amount, and controlling charging of the high-voltage battery such that the high-voltage battery is charged with a predetermined amount of electricity from the low-voltage battery on condition that the stored electricity amount of the low-voltage battery is greater than the determination stored electricity amount.

A program of the present disclosure is a program to be executed by a processing circuit when a high-voltage battery having a higher rated voltage than a low-voltage battery is charged from the low-voltage battery. The program causes the processing circuit to execute determining whether a stored electricity amount of the low-voltage battery is greater than a determination stored electricity amount, and controlling charging of the high-voltage battery such that the high-voltage battery is charged with a predetermined amount of electricity from the low-voltage battery on condition that the processing circuit determines that the stored electricity amount of the low-voltage battery is greater than the determination stored electricity amount.

A non-transitory storage medium of the present disclosure is a non-transitory storage medium that stores instructions. The instructions are executable by one or more processors and cause the one or more processors to execute functions of determining whether a stored electricity amount of a low-voltage battery is greater than a determination stored electricity amount, and controlling charging of a high-voltage battery having a higher rated voltage than the low-voltage battery such that the high-voltage battery is charged with a predetermined amount of electricity from the low-voltage battery on condition that the stored electricity amount of the low-voltage battery is greater than the determination stored electricity amount.

Even when the charging rate characteristic of the high-voltage battery changes, a sufficient amount of electricity can be stored in the high-voltage battery.

### BRIEF DESCRIPTION OF THE DRAWINGS

Features, advantages, and technical and industrial significance of exemplary embodiments of the present disclosure will be described below with reference to the accompanying drawings, in which like signs denote like elements, and wherein:

FIG. 1 is a block diagram schematically showing a vehicle including a battery system of an embodiment;

FIG. 2 is a block diagram showing a functional configuration of a control device included in the battery system of FIG. 1;

FIG. 3 is a flowchart showing a series of processes executed by the control device when a high-voltage battery is charged in the battery system of FIG. 1;

FIG. 4 is a diagram showing the relationship between the capacity and the electricity amount of a low-voltage battery included in the battery system of FIG. 1;

FIG. 5 is a flowchart showing a series of processes executed by the control device when a lower limit guard is set in the battery system of FIG. 1;

FIG. 6 is a flowchart showing a series of processes executed by the control device when a predetermined amount of electricity is set in the battery system of FIG. 1; and

FIG. 7 is a diagram showing changes in the amount of electricity stored in the high-voltage battery when charging of the high-voltage battery from the low-voltage battery is performed in the battery system of FIG. 1.

### DETAILED DESCRIPTION OF EMBODIMENTS

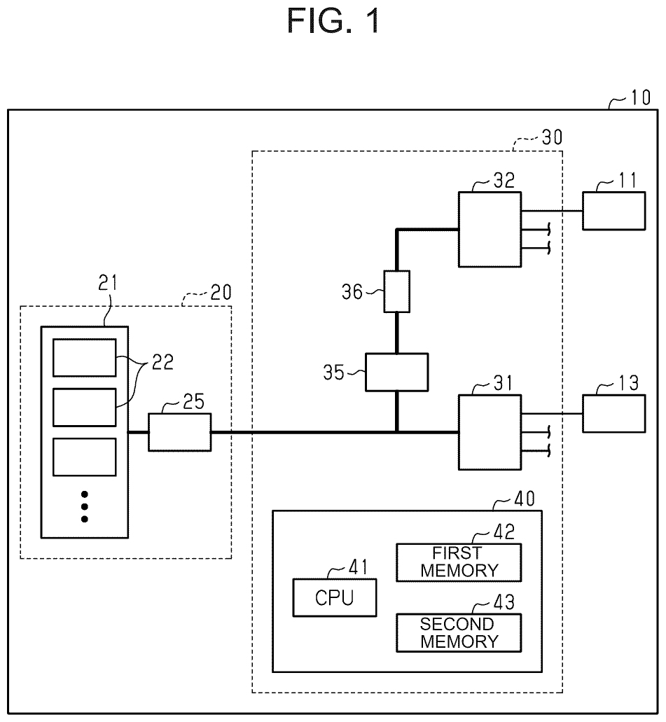

Hereinbelow, an embodiment of a battery system, a vehicle, a method of controlling a battery system, and a program will be described with reference to FIGS. 1 to 7.

### Configuration of Vehicle

FIG. 1 shows a vehicle 10 equipped with a battery system 30. The vehicle 10 further includes a solar power generation system 20, at least one traction motor 11, and a plurality of auxiliary machines 13. The traction motor 11 serves as a power source of the vehicle 10. The auxiliary machines 13 include an air conditioner, an acoustic device, a display device, and the like.

The solar power generation system 20 includes a solar panel 21, and a solar converter 25. The solar panel 21 includes a plurality of solar cells 22 that generates electric power by being irradiated with sunlight. For example, the solar panel 21 is installed on a roof of the vehicle 10. The solar converter 25 converts the voltage of the direct current electric power generated by the solar panel 21. The solar converter 25 then outputs the direct current electric power with the converted voltage to the battery system 30.

### Configuration of Battery System

The battery system 30 includes a low-voltage battery 31, and a high-voltage battery 32.

The low-voltage battery 31 is a secondary battery. The low-voltage battery 31 is, for example, a lithium ion battery. The rated voltage of the low-voltage battery 31 is, for example, approximately 12 [V] to 48 [V]. The low-voltage battery 31 supplies direct current electric power to components mounted on the vehicle 10 such as the auxiliary machines 13 described above.

The low-voltage battery 31 is charged with direct current electric power supplied from the solar power generation system 20. That is, the low-voltage battery 31 is charged with the direct current electric power that is output from the solar converter 25 and supplied to the low-voltage battery 31.

The high-voltage battery 32 is, for example, a battery for traveling of the vehicle 10. That is, the high-voltage battery 32 supplies direct current electric power to the traction motor 11 that is one of the components of the vehicle 10. The traction motor 11 is driven by the electric power supplied from the high-voltage battery 32. The rated voltage of the high-voltage battery 32 is higher than the rated voltage of the low-voltage battery 31.

The rated voltage of the high-voltage battery 32 is, for example, approximately 200 [V] to 250 [V].

The battery system 30 includes a bidirectional DC-DC converter 35, and a switch circuit 36. The bidirectional DC-DC converter 35 is a circuit that converts the voltage of direct current electric power input to the bidirectional DC-DC converter 35 and outputs the electric power with the converted voltage. For example, when charging of the high-voltage battery 32 from the low-voltage battery 31 is performed, the bidirectional DC-DC converter 35 boosts the voltage of direct current electric power output from the low-voltage battery 31 to supply the direct current electric power output from the low-voltage battery 31 to the high-voltage battery 32. When charging of the low-voltage battery 31 from the high-voltage battery 32 is performed, the bidirectional DC-DC converter 35 lowers the voltage of direct current electric power output from the high-voltage battery 32 to supply the direct current electric power output from the high-voltage battery 32 to the low-voltage battery 31.

The switch circuit 36 is installed, for example, on a power line that connects the bidirectional DC-DC converter 35 and the high-voltage battery 32 to each other. When the switch circuit 36 is turned off, the passage of electric current between the high-voltage battery 32 and the bidirectional DC-DC converter 35 is interrupted. When the switch circuit 36 is turned on, the passage of electric current between the high-voltage battery 32 and the bidirectional DC-DC converter 35 is allowed.

The battery system 30 includes a control device 40 that controls the entire system. The control device 40 is, for example, an electronic control unit. In this case, the control device 40 includes a CPU 41, a first memory 42, and a second memory 43. The CPU 41 is an example of the “processing circuit”. The first memory 42 stores a control program to be executed by the CPU 41. The second memory 43 stores calculation results and the like of the CPU 41. The CPU 41 controls charging of the high-voltage battery 32 from the low-voltage battery 31 by executing the control program stored in the first memory 42.

### Functional Units

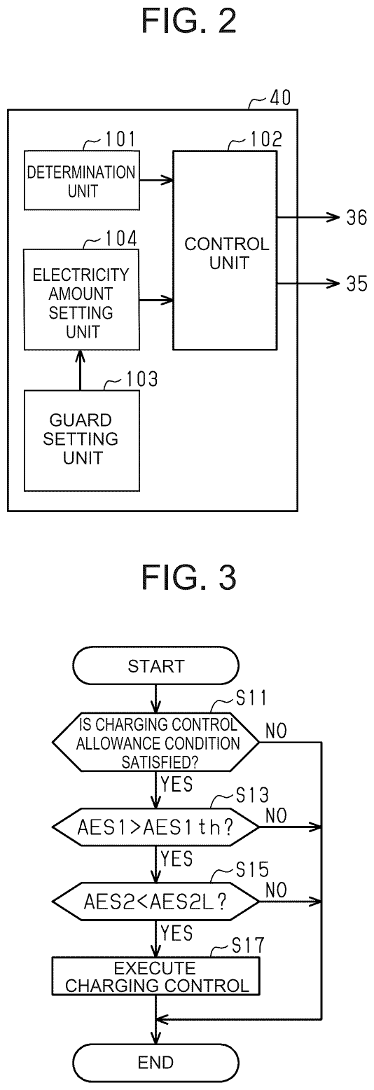

As shown in FIG. 2, the CPU 41 functions as various functional units by executing the control program stored in the first memory 42. The various functional units shown in FIG. 2 are functional units for controlling charging of the high-voltage battery 32 from the low-voltage battery 31. The various functional units include a determination unit 101, a control unit 102, a guard setting unit 103, and an electricity amount setting unit 104.

### Determination Unit

The determination unit 101 determines whether a stored electricity amount AES1 of the low-voltage battery 31 is greater than a determination stored electricity amount AES1th. The “stored electricity amount” described herein is the amount of electricity currently stored in the battery. The amount of electricity is the time integral of the electric energy. The determination stored electricity amount AES1th is a criterion for determining whether the stored electricity amount AES1 is sufficient at the time of supplying electric power from the low-voltage battery 31 to the high-voltage battery 32. When the stored electricity amount AES1 is equal to or less than the determination stored electricity amount AES1th, the stored electricity amount AES1 of the low-voltage battery 31 can be regarded as not being large. When the stored electricity amount AES1 is greater than the determination stored electricity amount AES1th, the stored electricity amount AES1 of the low-voltage battery 31 can be regarded as being large.

The determination unit 101 determines whether a stored electricity amount AES2 of the high-voltage battery 32 is equal to or greater than an upper limit amount AES2L. When the stored electricity amount of the high-voltage battery 32 fully charged at that point in time is defined as a stored electricity amount maximum value AES2max, the determination unit 101 sets a stored electricity amount slightly smaller than the stored electricity amount maximum value AES2max as the upper limit amount AES2L. A value based on which it can be determined that deterioration of the high-voltage battery 32 is likely to progress when the stored electricity amount AES2 exceeds the value is set as the upper limit amount AES2L. For example, the product of the stored electricity amount maximum value AES2max and a predetermined ratio may be set as the upper limit amount AES2L. In this case, the upper limit amount AES2L decreases as the stored electricity amount maximum value AES2max decreases.

### Control Unit

The control unit 102 controls charging of the high-voltage battery 32 such that the high-voltage battery 32 is charged with a predetermined amount of electricity QE from the low-voltage battery 31. At this time, the control unit 102 operates the bidirectional DC-DC converter 35 with the switch circuit 36 kept on to charge the high-voltage battery 32 with the predetermined amount of electricity QE from the low-voltage battery 31. Hereinbelow, the control of operating the bidirectional DC-DC converter 35 with the switch circuit 36 kept on to charge the high-voltage battery 32 from the low-voltage battery 31 is referred to as “charging control”.

The control unit 102 executes the charging control when the determination unit 101 determines that the stored electricity amount AES1 of the low-voltage battery 31 is greater than the determination stored electricity amount AES1th. In other words, the control unit 102 does not execute the charging control when the determination unit 101 determines that the stored electricity amount AES1 of the low-voltage battery 31 is equal to or less than the determination stored electricity amount AES1th.

The control unit 102 executes the charging control when the determination unit 101 determines that the stored electricity amount AES2 of the high-voltage battery 32 is less than the upper limit amount AES2L. In other words, the control unit 102 does not execute the charging control when the determination unit 101 determines that the stored electricity amount AES2 of the high-voltage battery 32 is equal to or greater than the upper limit amount AES2L.

When the control unit 102 executes the charging control, the stored electricity amount AES2 of the high-voltage battery 32 increases. As the stored electricity amount AES2 increases, a high-voltage battery voltage VB2 that is the voltage of the high-voltage battery 32 increases. The high-voltage battery voltage VB2 is the voltage between terminals of battery cells of the high-voltage battery 32. If the high-voltage battery voltage VB2 becomes too high, the stored electricity amount AES2 may significantly exceed the upper limit amount AES2L during the execution of the charging control. Thus, a voltage for determining whether the stored electricity amount AES2 has significantly exceeded the upper limit amount AES2L is set as a specified voltage VB2th. When the high-voltage battery voltage VB2 becomes higher than the specified voltage VB2th during the execution of the charging control, the control unit 102 stops the charging control. That is, the control unit 102 stops the charging control before the high-voltage battery 32 is charged with the predetermined amount of electricity QE.

### Guard Setting Unit

When direct current electric power of the low-voltage battery 31 is supplied to the high-voltage battery 32 to charge the high-voltage battery 32, the stored electricity amount AES1 of the low-voltage battery 31 decreases. As the stored electricity amount AES1 decreases, the voltage between terminals of battery cells that constitute the low-voltage battery 31 decreases. The voltage between the terminals of the battery cells that constitute the low-voltage battery 31 is simply referred to as the “low-voltage battery voltage VB1”.

A capacity CC1 of the low-voltage battery 31 is a maximum value of the amount of electricity that can be currently stored in the low-voltage battery 31. As the deterioration of the low-voltage battery 31 progresses, the capacity CC1 of the low-voltage battery 31 decreases. It is not preferable for the low-voltage battery voltage VB1 to become too low in a state in which the capacity CC1 has decreased.

Thus, the guard setting unit 103 sets a lower limit guard VG to restrain the low-voltage battery voltage VB 1 from becoming too low due to charging of the high-voltage battery 32 from the low-voltage battery 31. For example, the guard setting unit 103 determines whether the capacity CC1 of the low-voltage battery 31 is equal to or less than a threshold CC1th. Then, when the guard setting unit 103 determines that the capacity CC1 is equal to or less than the threshold CC1th, the guard setting unit 103 sets the lower limit guard VG. The guard setting unit 103 does not set the lower limit guard VG when the capacity CC1 is greater than the threshold CC1th.

### Electricity Amount Setting Unit

The electricity amount setting unit 104 sets the predetermined amount of electricity QE.

For example, the electricity amount setting unit 104 sets the predetermined amount of electricity QE in accordance with the state of the high-voltage battery 32. In this case, the electricity amount setting unit 104 obtains at least one of the charged state and the deteriorated state of the high-voltage battery 32 as the state of the high-voltage battery 32. In a case in which the electricity amount setting unit 104 obtains the charged state of the high-voltage battery 32, the electricity amount setting unit 104 obtains, for example, the stored electricity amount AES2 of the high-voltage battery 32. Then, the electricity amount setting unit 104 reduces the predetermined amount of electricity QE as the stored electricity amount AES2 of the high-voltage battery 32 increases. In a case in which the electricity amount setting unit 104 obtains the deteriorated state of the high-voltage battery 32, the electricity amount setting unit 104 obtains, for example, the current capacity CC2 of the high-voltage battery 32. Then, the electricity amount setting unit 104 reduces the predetermined amount of electricity QE as the capacity CC2 of the high-voltage battery 32 decreases.

If the predetermined amount of electricity QE is large even through the capacity CC1 of the low-voltage battery 31 becomes small due to deterioration of the low-voltage battery 31, the low-voltage battery voltage VB1 may become too low through one charging control. Thus, the electricity amount setting unit 104 determines whether the capacity CC1 of the low-voltage battery 31 is equal to or less than a determination capacity CCth. Then, the electricity amount setting unit 104 makes the predetermined amount of electricity QE smaller when the electricity amount setting unit 104 determines that the capacity CC1 of the low-voltage battery 31 is equal to or less than the determination capacity CCth than when the electricity amount setting unit 104 determines that the capacity CC1 is greater than the determination capacity CCth. In this case, a criterion for determining whether the capacity CC1 has become small is set as the determination capacity CCth.

As described above, when the capacity CC1 of the low-voltage battery 31 becomes small, the guard setting unit 103 sets the lower limit guard VG. Specifically, when the guard setting unit 103 determines that the capacity CC1 is equal to or less than the threshold CC1th, the guard setting unit 103 sets the lower limit guard VG. When the threshold CC1th is equal to the determination capacity CCth, the electricity amount setting unit 104 can make the predetermined amount of electricity QE smaller when the lower limit guard VG is set than when the lower limit guard VG is not set. For example, when the lower limit guard VG is set by the guard setting unit 103, the electricity amount setting unit 104 preferably sets the predetermined amount of electricity QE such that the low-voltage battery voltage VB1 does not fall below the lower limit guard VG. This is because the possibility that the low-voltage battery voltage VB1 at the end of the charging control is low increases as the predetermined amount of electricity QE increases.

In the charging control, the bidirectional DC-DC converter 35 and the switch circuit 36 are operated. As the number of times the bidirectional DC-DC converter 35 and switch circuit 36 are operated increases, deterioration of the bidirectional DC-DC converter 35 and switch circuit 36 is more likely to progress. Thus, the electricity amount setting unit 104 sets the predetermined amount of electricity QE such that the predetermined amount of electricity QE is larger when the frequency of executing the charging control is high than when the frequency of executing the charging control is low. The “frequency of executing the charging control” described herein refers to the number of times the charging control is executed within a predetermined time. The larger number of times the charging control is executed within the predetermined time means the higher frequency of executing the charging control.

### High-Voltage Battery Charging Process

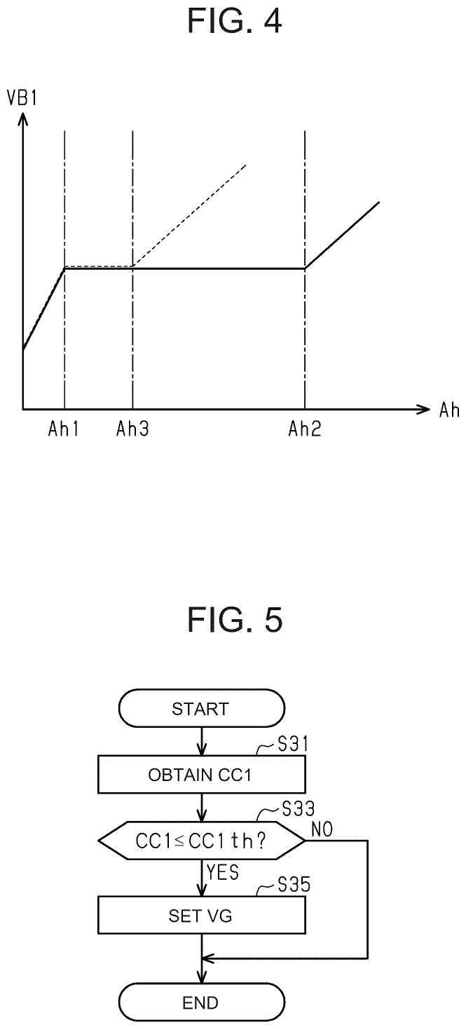

A high-voltage battery charging process executed by the CPU 41 will be described with reference to FIGS. 3 and 4. The high-voltage battery charging process is a series of processes for charging the high-voltage battery 32. The CPU 41 repeatedly executes the high-voltage battery charging process.

In step S11, the CPU 41 determines whether an allowance condition for the charging control is satisfied. For example, when the vehicle 10 is traveling, electric power is supplied from the high-voltage battery 32 to the traction motor 11. Thus, it is not preferable to execute the charging control when the vehicle 10 is traveling. Thus, the allowance condition preferably includes that the vehicle 10 is at a standstill. When the CPU 41 determines that the allowance condition is satisfied (S11: YES), the CPU 41 shifts the process to step S13. When the CPU 41 determines that the allowance condition is not satisfied (S11: NO), the CPU 41 finishes the high-voltage battery charging process once.

In step S13, the CPU 41 determines whether the stored electricity amount AES1 of the low-voltage battery 31 is greater than the determination stored electricity amount AES1th. When the CPU 41 determines that the stored electricity amount AES1 of the low-voltage battery 31 is greater than the determination stored electricity amount AES1th (S13: YES), the CPU 41 shifts the process to step S15. When the CPU 41 determines that the stored electricity amount AES1 of the low-voltage battery 31 is equal to or less than the determination stored electricity amount AES1th (S13: NO), the CPU 41 finishes the high-voltage battery charging process once.

An example of the process of determining whether the stored electricity amount AES1 is greater than the determination stored electricity amount AES1th will be described with reference to FIG. 4. FIG. 4 shows the relationship between the low-voltage battery voltage VB1 and an electricity amount Ah of the low-voltage battery 31.

As indicated by a solid line in FIG. 4, when the electricity amount Ah is not so large, that is, when the electricity amount Ah is equal to or greater than a first electricity amount Ah1 and less than a second electricity amount Ah2, the low-voltage battery voltage VB1 is substantially constant even when the electricity amount Ah changes. On the other hand, when the electricity amount Ah is relatively large, that is, when the electricity amount Ah is equal to or greater than the second electricity amount Ah2, the low-voltage battery voltage VB1 also increases as the electricity amount Ah increases.

Thus, the CPU 41 can determine whether the stored electricity amount AES1 is greater than the determination stored electricity amount AES1th based on the amount of change in the low-voltage battery voltage VB1 when the electricity amount Ah changes. In this case, the CPU 41 determines that the stored electricity amount AES1 is greater than the determination stored electricity amount AES1th when the amount of change in the low-voltage battery voltage VB1 when the electricity amount Ah changes is equal to or greater than a determination value. On the other hand, when the amount of change in the low-voltage battery voltage VB1 when the electricity amount Ah changes is less than the determination value, the CPU 41 determines that the stored electricity amount AES1 is equal to or less than the determination stored electricity amount AES1th.

A method that differs from the method described above with reference to FIG. 4 may be used as the process of determining whether the stored electricity amount AES1 is greater than the determination stored electricity amount AES1th. For example, the CPU 41 calculates the stored electricity amount AES1 of the low-voltage battery 31. Then, the CPU 41 may determine that the stored electricity amount AES1 is greater than the determination stored electricity amount AES1th when the calculated value of the stored electricity amount AES1 is greater than the determination stored electricity amount AES1th.

Referring back to FIG. 3, in step S15, the CPU 41 determines whether the stored electricity amount AES2 of the high-voltage battery 32 is less than the upper limit amount AES2L. For example, the CPU 41 calculates the stored electricity amount AES2 of the high-voltage battery 32. The CPU 41 determines that the stored electricity amount AES2 is less than the upper limit amount AES2L when the calculated value of the stored electricity amount AES2 is less than the upper limit AES2L. The CPU 41 determines that the stored electricity amount AES2 is equal to or greater than the upper limit amount AES2L when the calculated value of the stored electricity amount AES2 is equal to or greater than the upper limit amount AES2L. When the CPU 41 determines that the stored electricity amount AES2 is less than the upper limit amount AES2L (S15: YES), the CPU 41 shifts the process to step S17. When the CPU 41 determines that the stored electricity amount AES2 is equal to or greater than the upper limit amount AES2L (S15: NO), the CPU 41 finishes the high-voltage battery charging process once.

In step S17, the CPU 41 executes the charging control. The CPU 41 finishes the charging control when any one of the following conditions (A1) and (A2) is satisfied.

(A1) The high-voltage battery 32 is charged with the predetermined amount of electricity QE from the low-voltage battery 31.

(A2) The high-voltage battery voltage VB2 becomes higher than the specified voltage VB2th during the execution of the charging control.

The CPU 41 finishes the high-voltage battery charging process once when the charging control is finished.

Of the steps shown in FIG. 3, the processes of steps S11, S13 and S15 are executed by the CPU 41 functioning as the determination unit 101. The process of step S17 is executed by the CPU 41 functioning as the control unit 102.

### Guard Setting Process

A guard setting process executed by the CPU 41 will be described with reference to FIG. 5. The guard setting process is a series of processes for setting the lower limit guard VG. The CPU 41 executes the guard setting process when a predetermined condition is satisfied. Examples of the predetermined condition include that a user has got into the vehicle 10 and that an operation switch of the vehicle 10 has been turned on.

In step S31, the CPU 41 obtains the capacity CC1 of the low-voltage battery 31. In the subsequent step S33, the CPU 41 determines whether the capacity CC1 is equal to or less than the threshold CC1th. When the CPU 41 determines that the capacity CC1 is equal to or less than the threshold CC1th (S33: YES), the CPU 41 shifts the process to step S35. When the CPU 41 determines that the capacity CC1 is greater than the threshold CC1th (S33: NO), the CPU 41 finishes the guard setting process.

In step S35, the CPU 41 sets the lower limit guard VG. Then, the CPU 41 finishes the guard setting process.

The processes of steps S31, S33 and S35 shown in FIG. 5 are executed by the CPU 41 functioning as the guard setting unit 103.

### Electricity Amount Setting Process

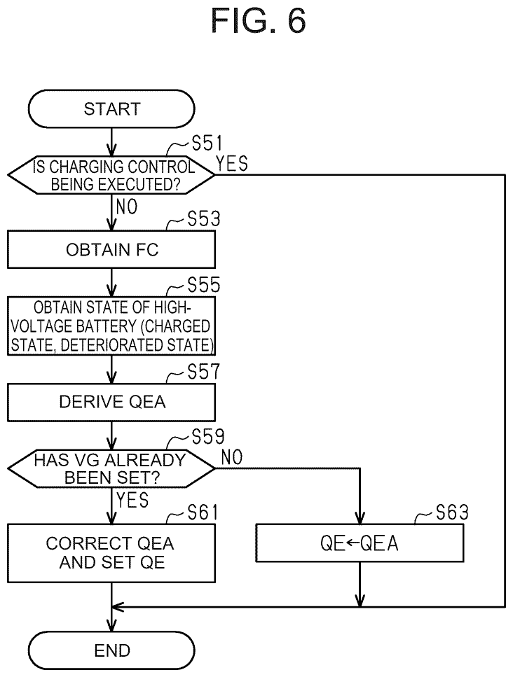

An electricity amount setting process executed by the CPU 41 will be described with reference to FIGS. 4 and 6. The electricity amount setting process is a series of processes for setting the predetermined amount of electricity QE. The CPU 41 executes the electricity amount setting process every predetermined control period.

As shown in FIG. 6, in step S51, the CPU 41 determines whether the charging control is being executed. When the CPU 41 determines that the charging control is being executed (S51: YES), the CPU 41 finishes the electricity amount setting process once. When the CPU 41 determines that the charging control is not being executed (S51: NO), the CPU 41 shifts the process to step S53.

In step S53, the CPU 41 obtains a frequency FC of executing the charging control. In the subsequent step S55, the CPU 41 obtains the charged state and the deteriorated state as the state of the high-voltage battery 32.

In the subsequent step S57, the CPU 41 derives an electricity amount provisional value QEA that is a provisional value of the predetermined amount of electricity QE. The CPU 41 derives the predetermined amount of electricity QE based on the frequency FC of executing the charging control and the state of the high-voltage battery 32 as the electricity amount provisional value QEA.

In the subsequent step S59, the CPU 41 determines whether the lower limit guard VG has been set by the execution of the guard setting process. When the lower limit guard VG has been set (S59: YES), the CPU 41 shifts the process to step S61. When the lower limit guard VG has not been set (S59: NO), the CPU 41 shifts the process to step S63.

In step S61, the CPU 41 sets the predetermined amount of electricity QE by correcting the electricity amount provisional value QEA such that the low-voltage battery voltage VB1 does not fall below the lower limit guard VG after the charging control is finished. It is needless to say that when the CPU 41 can determine that the low-voltage battery voltage VB1 does not fall below the lower limit guard VG even after the charging control is executed with the electricity amount provisional value QEA set as the predetermined amount of electricity QE, the CPU 41 may set the electricity amount provisional value QEA as the predetermined amount of electricity QE. After setting the predetermined amount of electricity QE, the CPU 41 finishes the electricity amount setting process once.

A dashed line in FIG. 4 shows the relationship between the low-voltage battery voltage VB1 and the electricity amount Ah when the low-voltage battery 31 is in deteriorated condition. On the other hand, a solid line in FIG. 4 shows the relationship between the low-voltage battery voltage VB1 and the electricity amount Ah when the low-voltage battery 31 is not in deteriorated condition. While a third electricity amount Ah3 is the electricity amount that serves as a criterion for determining whether the stored electricity amount AES1 is large when the low-voltage battery 31 is in deteriorated condition, a second electricity amount Ah2 is the electricity amount that serves as a criterion for determining whether the stored electricity amount AES1 is large when the low-voltage battery 31 is not in deteriorated condition. As shown in FIG. 4, the third electricity amount Ah3 is smaller than the second electricity amount Ah2.

Thus, the predetermined amount of electricity QE is preferably made smaller when the capacity CC of the low-voltage battery 31 has decreased to the extent that the lower limit guard VG is set than when the lower limit guard VG is not set.

Referring back to FIG. 6, in step S63, the CPU 41 sets the electricity amount provisional value QEA as the predetermined amount of electricity QE. Then, the CPU 41 finishes the electricity amount setting process once.

### Actions and Effects of the Present Embodiment

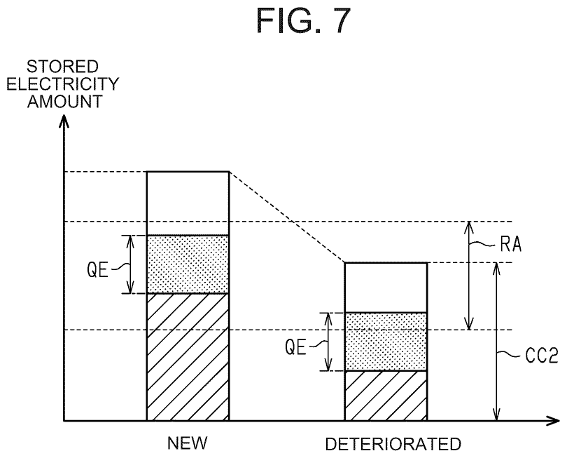

The actions and effects of the present embodiment will be described with reference to FIG. 7. A stored electricity amount range RA shown in FIG. 7 is the range of the stored electricity amount AES2 of the high-voltage battery 32 desired as a system.

The CPU 41 determines whether the stored electricity amount AES1 of the low-voltage battery 31 is greater than the determination stored electricity amount AES1th. When the CPU 41 determines that the stored electricity amount AES1 is greater than the determination stored electricity amount AES1th, the CPU 41 executes the charging control. In the charging control, the CPU 41 controls charging of the high-voltage battery 32 such that the high-voltage battery 32 is charged with the predetermined amount of electricity QE from the low-voltage battery 31.

FIG. 7 shows changes in the stored electricity amount AES2 of the high-voltage battery 32 caused by the execution of the charging control. More specifically, FIG. 7 shows a change in the stored electricity amount AES2 when the high-voltage battery 32 is new and a change in the stored electricity amount AES2 when the high-voltage battery 32 is in deteriorated condition.

In the present embodiment, regardless of whether the high-voltage battery 32 is in deteriorated condition, the high-voltage battery 32 is charged with the predetermined amount of electricity QE by executing the charging control. When the stored electricity amount AES2 of the high-voltage battery 32 is less than the upper limit amount AES2L, the charging control is repeatedly executed when the CPU 41 determines that the stored electricity amount AES1 of the low-voltage battery 31 is greater than the determination stored electricity amount AES1th. Thus, the battery system 30 can sufficiently ensure the stored electricity amount AES2 of the high-voltage battery 32 even when the charging rate characteristic of the high-voltage battery 32 changes. That is, the battery system 30 can make the stored electricity amount AES2 greater than the lower limit of the stored electricity amount range RA.

The charging rate characteristic is the characteristic that shows the relationship between the stored electricity amount AES2 and the charging rate of the high-voltage battery 32. As the deterioration of the high-voltage battery 32 progresses, the stored electricity amount maximum value AES2max decreases. Accordingly, the charging rate characteristic of the high-voltage battery 32 changes as the deterioration of the high-voltage battery 32 progresses.

In the present embodiment, the following effects can further be obtained. The low-voltage battery 31 is charged with direct current electric power supplied from the solar power generation system 20. Thus, in the battery system 30, both the low-voltage battery 31 and the high-voltage battery 32 can be charged with the electric power generated by the solar panel 21 of the solar power generation system 20.

The high-voltage battery 32 can supply electric power to the traction motor 11. The low-voltage battery 31 can supply electric power to the auxiliary machines 13. Thus, the vehicle 10 including the battery system 30 can travel using the electric power generated by the solar panel 21.

The bidirectional DC-DC converter 35 is installed on the power line between the low-voltage battery 31 and the high-voltage battery 32. This enables the battery system 30 to charge the high-voltage battery 32 from the low-voltage battery 31 through the bidirectional DC-DC converter 35 and charge the low-voltage battery 31 from the high-voltage battery 32 through the bidirectional DC-DC converter 35.

The CPU 41 sets the predetermined amount of electricity QE in accordance with the state of the high-voltage battery 32. This enables the battery system 30 to restrain the occurrence of excessive supply of electric power to the high-voltage battery 32 caused by executing the charging control.

For example, the CPU 41 can reduce the predetermined amount of electricity QE as the stored electricity amount AES2 of the high-voltage battery 32 increases. For example, the CPU 41 can make the predetermined amount of electricity QE smaller when deterioration of the high-voltage battery 32 has progressed than when the deterioration has not progressed.

As the number of times the electronic circuits such as the bidirectional DC-DC converter 35 and the switch circuit 36 are operated increases, the possibility of occurrence of an abnormality such as a malfunction of the electronic circuits increases.

During fine weather, the solar panel 21 generates more electric power than during cloudy weather and rainy weather. Thus, during fine weather, the length of a period from when the charging control is finished to when the stored electricity amount AES1 of the low-voltage battery 31 exceeds the determination stored electricity amount AES1th is shortened. As a result, the frequency FC of executing the charging control is likely to increase.

In this point, in the battery system 30, the CPU 41 sets the predetermined amount of electricity QE such that the predetermined amount of electricity QE is made larger when the frequency FC of executing the charging control is high than when the frequency FC is low. This can restrain an increase in the number of times the bidirectional DC-DC converter 35 and the switch circuit 36 are operated for charging the high-voltage battery 32. Thus, in the battery system 30, an abnormality in the electronic circuits such as the bidirectional DC-DC converter 35 and the switch circuit 36 is unlikely to occur.

As the deterioration of the low-voltage battery 31 progresses, the capacity CC1 of the low-voltage battery 31 decreases. Furthermore, the low-voltage battery 31 supplies electric power to the auxiliary machines 13. Thus, when the high-voltage battery 32 is charged with a large amount of electricity with the capacity CC1 lowered, the low-voltage battery voltage VB1 may become too low, which may cause the operation of the auxiliary machines 13 to become unstable.

Thus, in the battery system 30, when the CPU 41 makes the predetermined amount of electricity QE smaller when the CPU 41 determines that the capacity CC1 of the low-voltage battery 31 is equal to or less than the determination capacity CCth than when the CPU 41 determines that the capacity CC1 of the low-voltage battery 31 is greater than the determination capacity CCth. This makes it possible to restrain the low-voltage battery voltage VB1 from becoming too low due to the execution of the charging control. As a result, in the battery system 30, it is possible to restrain the operation of the auxiliary machines 13 supplied with electric power from the low-voltage battery 31 from becoming unstable due to the execution of the charging control.

For example, the CPU 41 sets the predetermined amount of electricity QE such that the low-voltage battery voltage VB1 does not fall below the lower limit guard VG.

Accordingly, the CPU 41 can make the predetermined amount of electricity QE smaller when the CPU 41 determines that the capacity CC1 of the low-voltage battery 31 is equal to or less than the determination capacity CCth than when the CPU 41 determines that the capacity CC1 is greater than the determination capacity CCth.

As the deterioration of the low-voltage battery 31 progresses, the capacity CC1 of the low-voltage battery 31 decreases. When the CPU 41 determines that the capacity CC1 is equal to or less than the threshold CC1th, the CPU 41 sets the lower limit guard VG. This enables the battery system 30 to restrain the low-voltage battery voltage VB1 from becoming too low due to the execution of the charging control when the deterioration of the low-voltage battery 31 progresses.

On the other hand, when the CPU 41 determines that the capacity CC1 is greater than the threshold CC1th, the CPU 41 does not set the lower limit guard VG. Thus, when the low-voltage battery 31 has not so deteriorated, the CPU 41 can set the predetermined amount of electricity QE to a relatively large value. This enables the battery system 30 to restrain the frequency FC of executing the charging control from becoming high when the low-voltage battery 31 has not so deteriorated.

When the high-voltage battery voltage VB2 becomes higher than the specified voltage VB2th during the execution of the charging control, the CPU 41 forcibly finishes the charging control. This enables the battery system 30 to restrain excessive electric power from being supplied to the high-voltage battery 32.

### Modifications

The above embodiment can be carried out with the following modifications. The above embodiment and the following modifications can be combined with each other as long as no technical inconsistency arises.

The CPU 41 may set the lower limit guard VG regardless of the magnitude of the capacity CC1 of the low-voltage battery 31. In this case, the CPU 41 may change the lower limit guard VG in accordance with the magnitude of the capacity CC1. For example, the CPU 41 may set the lower limit guard VG to a smaller value as the capacity CC1 increases.

The CPU 41 does not have to set the lower limit guard VG as long as the CPU 41 can make the predetermined amount of electricity QE smaller when the CPU 41 determines that the capacity CC1 of the low-voltage battery 31 is equal to or less than the determination capacity CCth than when the CPU 41 determines that the capacity CC1 of the low-voltage battery 31 is greater than the determination capacity CCth.

The CPU 41 does not have to change the predetermined amount of electricity QE in accordance with the capacity CC1 of the low-voltage battery 31. For example, when the low-voltage battery voltage VB1 becomes equal to or less than a reference voltage during the execution of the charging control, the CPU 41 may forcibly finish the charging control. In this case, a criterion for determining whether the low-voltage battery voltage VB1 has become too low is preferably set as the reference voltage. This enables the CPU 41 to restrain the low-voltage battery voltage VB1 from becoming too low during the execution of the charging control.

The CPU 41 does not have to change the predetermined amount of electricity QE in accordance with the frequency FC of executing the charging control.

The state of the high-voltage battery 32 may change depending on the temperature of the high-voltage battery 32 or the ambient temperature around the high-voltage battery 32. Thus, the CPU 41 may obtain the temperature of the high-voltage battery 32 or the ambient temperature around the high-voltage battery 32 as the state of the high-voltage battery 32. In this case, the CPU 41 may change the predetermined amount of electricity QE based on the temperature of the high-voltage battery 32 or the ambient temperature around the high-voltage battery 32.

When the CPU 41 takes the charged state of the high-voltage battery 32 into consideration, the CPU 41 may set the predetermined amount of electricity QE without taking the deteriorated state of the high-voltage battery 32 into consideration.

When the CPU 41 takes the deteriorated state of the high-voltage battery 32 into consideration, the CPU 41 may set the predetermined amount of electricity QE without taking the charged state of the high-voltage battery 32 into consideration.

The CPU 41 does not have to change the predetermined amount of electricity QE in accordance with the state of the high-voltage battery 32.

The CPU 41 may fix the predetermined amount of electricity QE at a preset value. In this case, the CPU 41 preferably monitors the state of the high-voltage battery 32 and the low-voltage battery 31 during the execution of the charging control. Then, the CPU 41 preferably finishes the charging control even in the middle of the charging control depending on the state of the high-voltage battery 32 and the low-voltage battery 31.

The CPU 41 may use an amount of energy [Wh] of the low-voltage battery 31 to determine whether the stored electricity amount AES1 of the low-voltage battery 31 is greater than the determination stored electricity amount AES1th. For example, when an amount of energy corresponding to the determination stored electricity amount AES1th is defined as a determination energy amount, the CPU 41 may determine that the stored electricity amount AES1 is greater than the determination stored electricity amount AES1th when the amount of energy of the low-voltage battery 31 is greater than the determination energy amount. In the charging control, the CPU 41 may control charging of the high-voltage battery 32 such that a predetermined amount of energy is transferred from the low-voltage battery 31 to the high-voltage battery 32. The “predetermined amount of energy” is a value obtained by converting the predetermined amount of electricity QE into the amount of energy.

It is only required that the battery system be configured to be capable of charging the high-voltage battery 32 from the low-voltage battery 31. Thus, it is only required that a DC-DC converter capable of boosting the voltage of direct current electric power of the low-voltage battery 31 be disposed on the power line between the low-voltage battery 31 and the high-voltage battery 32. That is, a DC-DC converter that does not have the function of lowering the voltage of direct current electric power of the high-voltage battery 32 may be disposed on the power line instead of the bidirectional DC-DC converter 35.

The low-voltage battery 31 may be a battery that is charged with electric power supplied from an electric power supply source other than the solar power generation system. Examples of the electric power supply source other than the solar power generation system include a generator that generates regenerative energy during braking of the vehicle 10 and a commercial power source.

The battery system may be embodied as a system other than the battery system 30 mounted on the vehicle 10.

The control device 40 is not limited to one that includes a CPU and a ROM and performs software processing. That is, the control device 40 may have any of the following configurations (a), (b) and (c).

(a) The control device 40 includes one or more processors that execute various processes in accordance with a computer program. The processors include a CPU, and one or more memories such as a RAM and a ROM. The memory stores program code or a command configured to cause the CPU to execute the processes. The memory, that is, a computer readable medium includes any available medium that can be accessed by a general or dedicated computer.

(b) The control device 40 includes one or more dedicated hardware circuits that execute various processes. The dedicated hardware circuit is, for example, an application specific integrated circuit, that is, an ASIC or an FPGA. Note that ASIC is an abbreviation for “application specific integrated circuit”, and FPGA is an abbreviation for “field programmable gate array”.

(c) The control device 40 includes one or more processors that execute some of the various processes in accordance with a computer program, and one or more dedicated hardware circuits that execute the rest of the various processes.

The expression “at least one” used in the present specification means “one or more” of the desired options. As an example, when the number of options is two, the expression “at least one” used in the present specification means “only one of the two options” or “both of the two options”. As another example, when the number of options is three or more, the expression “at least one” used in the present specification means “only one of the options” or “any combination of two or more of the options”.

### Technical Ideas

Technical ideas that can be understood from the embodiment and the modifications will be described as a supplement.

### Supplementary Item 1

A battery system including: a low-voltage battery; a high-voltage battery having a higher rated voltage than the low-voltage battery; and a processing circuit that controls charging of the high-voltage battery from the low-voltage battery, in which
the processing circuit executes
determining whether a stored electricity amount of the low-voltage battery is greater than a determination stored electricity amount, and
controlling charging of the high-voltage battery such that the high-voltage battery is charged with a predetermined amount of electricity from the low-voltage battery when the processing circuit determines that the stored electricity amount of the low-voltage battery is greater than the determination stored electricity amount.

### Supplementary Item 2

The battery system according to supplementary item 1, in which the low-voltage battery is charged with electric power supplied from a solar power generation system.

### Supplementary Item 3

The battery system according to supplementary item 1 or 2, in which
the battery system is mounted on a vehicle, and
the low-voltage battery and the high-voltage battery are configured to supply electric power to a component mounted on the vehicle.

### Supplementary Item 4

The battery system according to any one of supplementary items 1 to 3, further including a bidirectional DC-DC converter, in which the processing circuit boosts a voltage of direct current electric power output from the low-voltage battery to charge the high-voltage battery from the low-voltage battery.

### Supplementary Item 5

The battery system according to any one of supplementary items 1 to 4, in which the processing circuit sets the predetermined amount of electricity in accordance with a state of the high-voltage battery.

### Supplementary Item 6

The battery system according to any one of supplementary items 1 to 4, in which the processing circuit sets the predetermined amount of electricity based on at least one of a charged state and a deteriorated state of the high-voltage battery.

### Supplementary Item 7

The battery system according to any one of supplementary items 1 to 6, in which the processing circuit sets the predetermined amount of electricity such that the predetermined amount of electricity is greater when a frequency of charging the high-voltage battery from the low-voltage battery is high than when the frequency is low.

### Supplementary Item 8

The battery system according to any one of supplementary items 1 to 7, in which the processing circuit executes
determining whether a capacity of the low-voltage battery is equal to or less than a determination capacity, and
making the predetermined amount of electricity smaller when the processing circuit determines that the capacity of the low-voltage battery is equal to or less than the determination capacity than when the processing circuit determines that the capacity is greater than the determination capacity.

### Supplementary Item 9

The battery system according to any one of supplementary items 1 to 7, in which the processing circuit sets the predetermined amount of electricity such that a voltage of the low-voltage battery does not fall below a lower limit guard.

### Supplementary Item 10

The battery system according to supplementary item 9, in which the processing circuit sets the lower limit guard when the processing circuit determines that a capacity of the low-voltage battery is equal to or less than a threshold.

### Supplementary Item 11

The battery system according to any one of supplementary items 1 to 10, in which when a voltage of the high-voltage battery becomes higher than a specified voltage while charging of the high-voltage battery from the low-voltage battery is being performed, the processing circuit stops the charging of the high-voltage battery.

### Supplementary Item 12

A vehicle including: the battery system according to any one of supplementary items 1 to 11; and a traction motor that is driven by electric power supplied from the high-voltage battery.

What is claimed is:

1. A battery system comprising:
a low-voltage battery;
a high-voltage battery having a higher rated voltage than the low-voltage battery; and
a processing circuit configured to control charging of the high-voltage battery from the low-voltage battery, wherein
the processing circuit is configured to execute
determining whether a stored electricity amount of the low-voltage battery is greater than a determination stored electricity amount, and
controlling charging of the high-voltage battery such that the high-voltage battery is charged with a predetermined amount of electricity from the low-voltage battery on condition that the processing circuit determines that the stored electricity amount of the low-voltage battery is greater than the determination stored electricity amount.

2. The battery system according to claim 1, wherein the low-voltage battery is configured to be charged with electric power supplied from a solar power generation system.

3. The battery system according to claim 1, wherein:
the battery system is mounted on a vehicle; and
the low-voltage battery and the high-voltage battery are configured to supply electric power to a component mounted on the vehicle.

4. The battery system according to claim 1, further comprising a bidirectional DC-DC converter, wherein the processing circuit is configured to boost a voltage of direct current electric power output from the low-voltage battery to charge the high-voltage battery from the low-voltage battery.

5. The battery system according to claim 1, wherein the processing circuit is configured to set the predetermined amount of electricity in accordance with a state of the high-voltage battery.

6. The battery system according to claim 1, wherein the processing circuit is configured to set the predetermined amount of electricity based on at least one of a charged state and a deteriorated state of the high-voltage battery.

7. The battery system according to claim 1, wherein the processing circuit is configured to set the predetermined amount of electricity such that the predetermined amount of electricity is greater when a frequency of charging the high-voltage battery from the low-voltage battery is high than when the frequency is low.

8. The battery system according to claim 1, wherein
the processing circuit is configured to execute
determining whether a capacity of the low-voltage battery is equal to or less than a determination capacity, and
making the predetermined amount of electricity smaller when the processing circuit determines that the capacity of the low-voltage battery is equal to or less than the determination capacity than when the processing circuit determines that the capacity is greater than the determination capacity.

9. The battery system according to claim 1, wherein the processing circuit is configured to set the predetermined amount of electricity such that a voltage of the low-voltage battery does not fall below a lower limit guard.

10. The battery system according to claim 9, wherein the processing circuit is configured to set the lower limit guard on condition that the processing circuit determines that a capacity of the low-voltage battery is equal to or less than a threshold.

11. The battery system according to claim 1, wherein, on condition that a voltage of the high-voltage battery becomes higher than a specified voltage while charging of the high-voltage battery from the low-voltage battery is being performed, the processing circuit is configured to stop the charging of the high-voltage battery.

12. A vehicle comprising:
the battery system according to claim 1; and
a traction motor configured to be driven by electric power supplied from the high-voltage battery.

13. A method of controlling a battery system, the battery system including a low-voltage battery, and a high-voltage battery having a higher rated voltage than the low-voltage battery, the method comprising:
determining whether a stored electricity amount of the low-voltage battery is greater than a determination stored electricity amount; and
controlling charging of the high-voltage battery such that the high-voltage battery is charged with a predetermined amount of electricity from the low-voltage battery on condition that the stored electricity amount of the low-voltage battery is greater than the determination stored electricity amount.

14. A non-transitory storage medium that stores instructions, the instructions being executable by one or more processors and causing the one or more processors to execute functions of:
determining whether a stored electricity amount of a low-voltage battery is greater than a determination stored electricity amount; and
controlling charging of a high-voltage battery having a higher rated voltage than the low-voltage battery such that the high-voltage battery is charged with a predetermined amount of electricity from the low-voltage battery on condition that the stored electricity amount of the low-voltage battery is greater than the determination stored electricity amount.
